(19) United States
(12) Patent Application Publication
(10) Pub. No.: US 2010/0255672 A1
(43) Pub. Date: Oct. 7, 2010

(54) Method of manufacturing semiconductor device

(75) Inventor: Toru Kidokoro, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 12/662,200

(22) Filed: Apr. 5, 2010

(30) Foreign Application Priority Data
Apr. 6, 2009 (JP) 2009-092116

(51) Int. Cl. H01L 21/8247

(52) U.S. Cl. 438/594; 438/258; 257/E21.68

(57) ABSTRACT

A method of manufacturing a semiconductor device, includes 5 steps. The first step is a step of forming a floating gate on a first surface region of a semiconductor substrate through a gate insulating film. The second step is a step of forming a tunnel insulating film so as to cover a second surface region adjacent to the first surface region and an end portion of the floating gate. The third step is a step of forming an oxide film so as to cover the tunnel insulating film and be thicker at a portion above the second surface region than at a portion above the floating gate. The fourth step is a step of etching back the oxide film and a surface of the tunnel insulating film on the floating gate. The fifth step is a step of forming a control gate on the tunnel insulating film on the second surface region.

### INCORPORATIION BY REFERENCE

This application is based upon and claims the benefit of priority from Japanese patent application No. 2009-092116 filed on Apr. 6, 2009, the disclosure of which is incorporated herein in its entirety by reference.

### BACKGROUND OF THE INVENTION

1. Field of the Invention

The present invention relates to a method of manufacturing a semiconductor device, in particular, a method of manufacturing a semiconductor device having a flash memory.

2. Description of Related Art

Among nonvolatile memories, those capable of electrically writing/erasing data are classified as EEPROMs (Electrically Erasable Programmable Read-Only Memory). The EEPROMs capable of erasing data all together are referred to as flash memories. Especially, the flash memory called as Super Flash made by U.S. SST Inc. (Silicon Storage Technology, Inc.) is excellent in integration density and thus, widely used (Non patent literature 1: “Super Flash EEPROM Technology”, SST, Inc. Technical Paper (2001); http://www.sst.com/technology/superflash/701.xhtml).

FIG. 1 is a sectional view showing an example of a configuration of a flash memory (nonvolatile semiconductor memory). This nonvolatile semiconductor memory includes a gate insulating film 104, a floating gate 105, a spacer layer 106, a first side wall insulating film 110, a tunnel insulating film 108, a control gate 109, a second side wall insulating film 111, source/drain regions 103, 112, a source/drain electrode 107 and a silicide layer 113.

The source/drain regions 103, 112 are formed on a surface region of a well 102 on a semiconductor substrate 101 made of silicon, for example, so as to sandwich a channel region therebetween. Low-density regions extend from the source/drain regions 103, 112 toward the channel region. The source/drain regions 103, 112 are N+ silicon layers, for example. The silicide layer 113 exemplified by a cobalt silicide film is formed on the source/drain region 112. The source/drain electrode 107is formed on the source/drain region 103. The silicide layer 113 exemplified by a cobalt silicide film is formed on the source/drain electrode 107.

The gate insulating film 104 is formed on the channel region on a side of the source/drain region 103. The gate insulating film 104 is formed of a silicon oxide film, for example. The floating gate 105 is formed on the gate insulating film 104 and has an acute-angled portion extending with an acute angle at an upper end thereof on a side of the control gate 109. The floating gate 105 emits electrons mainly from the acute-angled portion to the control gate 109 at an erasure operation. The floating gate 105 is made of polysilicon, for example. The spacer layer 106 is formed on the floating gate 105 except for an end of the acute-angled portion. The spacer layer 106 is formed of a silicon oxide film, for example. The first side wall insulating film 110 is formed so as to cover side surfaces of the gate insulating film 104, the floating gate 105 and the spacer layer 106 on a side of the source/drain electrode 107. The first side wall insulating film 110 is formed of a silicon oxide film, for example.

The tunnel insulating film 108 is formed so as to cover the channel region on a side of the source/drain region 112, and side surfaces of the gate insulating film 104, the floating gate 105 and the spacer layer 106. The tunnel insulating film 108 is formed of a silicon oxide film, for example. The control gate 109 is formed so as to cover the tunnel insulating film 108. The side surface of the control gate 109 is separated from the gate insulating film 104, the floating gate 105 and the spacer layer 106 through the tunnel insulating film 108. The control gate 109 is made of polysilicon, for example. The silicide layer 113 exemplified by a cobalt silicide film is formed on the control gate 109. The second side wall insulating film 111 is formed so as to cover a side surface of the control gate 109 on an opposite side of the floating gate 105. The second side wall insulating film 111 is formed of a silicon oxide film, for example.

As a related technique, Japanese patent publication JP 2001-230331A (Patent literature 1) discloses a nonvolatile semiconductor memory and a method of manufacturing the nonvolatile semiconductor memory. The nonvolatile semiconductor memory includes a floating gate, a tunnel insulating film, a control gate and a diffusion region. The floating gate is formed on a semiconductor substrate through a gate insulating film. The tunnel insulating film is formed so as to coat the floating gate. The control gate is formed to extend over an upper portion and side portions of the floating gate through the tunnel insulating film. The diffusion region is formed so as to be adjacent to the floating gate or the control gate. A thickness of the tunnel insulating film formed on an upper position of the floating gate is smaller than that of the tunnel insulating film formed on a lower position of the floating gate. A selective oxide film made by a selective oxidation method is formed on the floating gate and a sharpened portion may be formed at an upper corner portion of the selective oxide film.

The method of manufacturing this nonvolatile semiconductor memory includes steps of forming the floating gate on the semiconductor substrate through the gate insulating film, forming the tunnel insulating film so as to coat the floating gate based on a CVD method, forming an embedding film up to a desired position where a lower portion of the floating gate is embedded, etching the tunnel insulating film formed on the floating gate by a predetermined amount by using the embedding film as a mask, forming the control gate so as to extend over the upper portion and the side portions of the floating gate through a tunnel oxide film after removing the embedding film, and forming the diffusion region so as to be adjacent to the floating gate or the control gate. The embedding film may be a resist film.

Inventor has now discovered the following facts.

Inventor's research has firstly revealed that in the nonvolatile semiconductor memory as shown in FIG. 1, the tunnel insulating film has the following problem in association with further miniaturization, integration and speeding-up of elements in recent years. FIG. 2 is a sectional view showing a problem of the tunnel insulating film in the nonvolatile semiconductor memory shown in FIG. 1. FIG. 2 is a partially enlarged view of FIG. 1. The tunnel insulating film 108 is continuously and integrally formed between the control gate 109 (side surface) and the floating gate 105, and between the control gate 109 (bottom surface) and the well 102 on the semiconductor substrate 101. In other words, a thickness of the tunnel insulating film 108 between the control gate 109 and the floating gate 105 is substantially the same as that of the tunnel insulating film 108 between the control gate 109 and the well 102 (semiconductor substrate 101). In addition, the tunnel insulating film 108 functions as the tunnel insulating film between the control gate 109 and the floating gate 105, as well as the gate insulating film between the control gate 109 and the well 102.

Data stored in this nonvolatile semiconductor memory is erased by applying a high voltage to the control gate 109 and extracting electrons accumulated on the floating gate 105 by use of an F-N (Fowler-Nordheim) current. However, as shown in FIG. 2, with such a configuration, depending on magnitude of the high voltage applied to the control gate 109 in order to erase the data, not only an F-N current 121 flows from the floating gate 105 to the control gate 109, but also an F-N current 122 may flow from the well 102 on the semiconductor substrate 101 to the control gate 109. As a result, disadvantageously, the insulating film (tunnel insulating film 108) between the well 102 (semiconductor substrate 101) and the control gate 109 is easy to break out, thereby decreasing the guaranteed number of times of rewriting.

To solve this problem, Inventor has devised a method of making the thickness of the tunnel insulating film 108 between the control gate 109 (bottom surface) and the well 102 of the semiconductor substrate 101 larger than the thickness of the tunnel insulating film 108 between the control gate 109 (side surface) and the floating gate 105. Thereby, irrespective of magnitude of the high voltage applied to the control gate 109 in order to erase the data, the F-N current 122 can be prevented from flowing from the well 102 on the semiconductor substrate 101 to the control gate 109. The method Inventor has devised will be described later.

The patent literature 1 discloses the manufacturing method of making an oxide film (33A) formed on an upper portion of the floating gate (4) smaller than the oxide film (33A) formed on a lower portion of the floating gate (4). According to the manufacturing method, first, a resist film (PR) is formed over the whole surface. Next, the resist (PR) is etched back by a predetermined amount and left up to a position where the lower portion of the floating gate (4) is embedded. Then, the oxide film (33A) is etched by using the resist (PR) as a mask. Thereby, the oxide film (33A) formed on the upper portion of the floating gate (4) is made thinner than the oxide film (33A) formed on the lower portion of the floating gate (4) (FIG. 8 in Patent literature 1).

However, according to the method in patent literature 1 using the resist, since the resist directly contacts with the tunnel oxide film and the gate oxide film, the resist may contaminate an interface of each oxide film. Such contamination can exert a negative effect on a writing operation, a reading operation and an erasure operation. As a result, reliability of the nonvolatile semiconductor memory may be lowered.

There is a demand for a technique of preventing contamination of the interface of each oxide film and suppressing breakdown of the insulating film between the semiconductor substrate and the control gate without lowering the reliability of the nonvolatile semiconductor memory.

### SUMMARY

The present invention seeks to solve one or more of the above problems, or to improve upon those problems at least in part.

In one embodiment, a method of manufacturing a semiconductor device includes: forming a floating gate on a first surface region of a semiconductor substrate through a gate insulating film; forming a tunnel insulating film so as to cover a second surface region adjacent to the first surface region and an end portion of the floating gate; forming an oxide film so as to cover the tunnel insulating film and be thicker at a portion above the second surface region than at a portion above the floating gate; etching back the oxide film and a surface of the tunnel insulating film on the floating gate; and forming a control gate on the tunnel insulating film on the second surface region.

According to the present invention, it is possible to prevent contamination of the interface of the insulating film and suppress breakdown of the insulating film between the semiconductor substrate and the control gate without lowering the reliability of the nonvolatile semiconductor memory.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view showing one example of a configuration of a typical nonvolatile semiconductor memory;

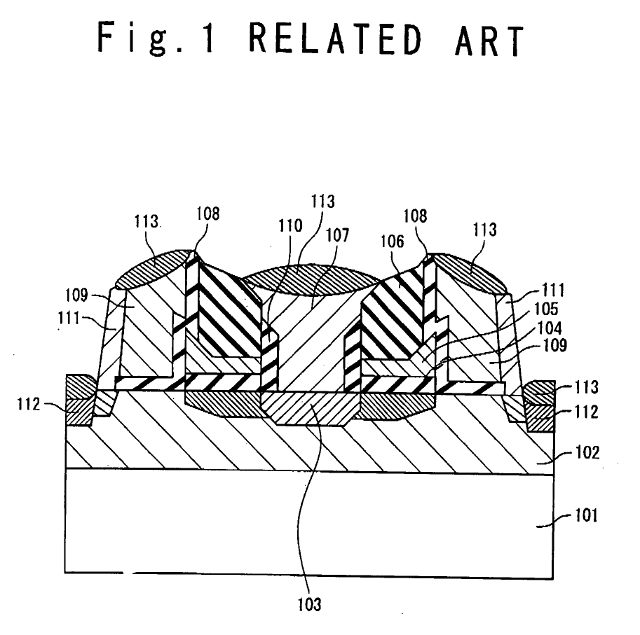

FIG. 2 is a sectional view showing a problem of a tunnel insulating film in the nonvolatile semiconductor memory shown in FIG. 1;

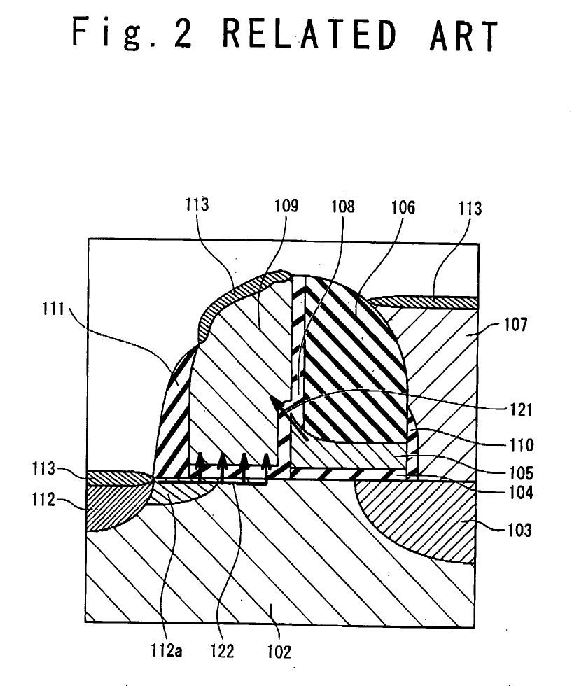

FIG. 3 is a sectional view showing a configuration of a semiconductor device according to an embodiment of the present invention;

FIG. 4 is a sectional view showing one of features of the nonvolatile semiconductor memory according to the embodiment of the present invention;

FIG. 5 is a sectional view showing a method of manufacturing the semiconductor device according to the embodiment of the present invention;

FIG. 6 is a sectional view showing the method of manufacturing the semiconductor device according to the embodiment of the present invention;

FIG. 7 is a sectional view showing the method of manufacturing the semiconductor device according to the embodiment of the present invention;

FIG. 8 is a sectional view showing the method of manufacturing the semiconductor device according to the embodiment of the present invention;

FIG. 9, is a sectional view showing the method of manufacturing the semiconductor device according to the embodiment of the present invention;

FIG. 10 is a sectional view showing the method of manufacturing the semiconductor device according to the embodiment of the present invention;

FIG. 11 is a sectional view showing the method of manufacturing the semiconductor device according to the embodiment of the present invention;

FIG. 12 is a sectional view showing the method of manufacturing the semiconductor device according to the embodiment of the present invention;

FIG. 13 is a sectional view showing the method of manufacturing the semiconductor device according to the embodiment of the present invention;

FIG. 14 is a sectional view showing the method of manufacturing the semiconductor device according to the embodiment of the present invention;

FIG. 15 is a sectional view showing the method of manufacturing the semiconductor device according to the embodiment of the present invention; and

FIG. 16 is a sectional view showing another variation of the method of manufacturing the semiconductor device according to the embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

An embodiment of a method of manufacturing a semiconductor device of the present invention will be described below referring to attached drawings.

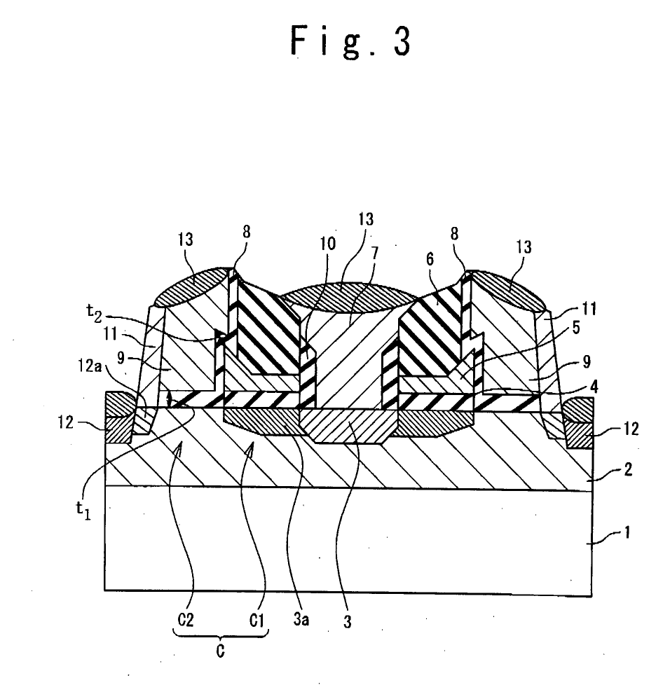

First, a configuration of the semiconductor device according to the embodiment of the present invention will be described. FIG. 3 is a sectional view showing the configuration of the semiconductor device according to the embodiment of the present invention. This semiconductor device shows a nonvolatile semiconductor memory (ex. flash memory). The nonvolatile semiconductor memory includes a gate insulating film 4, a floating gate 5, a spacer layer 6, a first side wall insulating film 10, a tunnel insulating film 8, a control gate 9, a second side wall insulating film 11, source/drain regions 3, 12, a source/drain electrode 7 and a silicide layer 13.

The source/drain regions 3, 12 are formed on a surface region of the well 2 on the semiconductor substrate 1 made of silicon, for example, so as to sandwich a channel region C therebetween. Low-density regions 3a, 12a extend from the source/drain regions 3, 12 toward the channel region C. The source/drain regions 3, 12 are formed of N+ silicon layers, for example. The silicide layer 13 exemplified by a cobalt silicide film is formed on the source/drain region 12. The source/drain electrode 7 is formed on the source/drain region 3. The silicide layer 13 exemplified by a cobalt silicide film is formed on the source/drain electrode 7.

The gate insulating film 4 is formed on a region in the channel region C on a side of the source/drain region 3 (that is, a first surface region C1). The gate insulating film 4 is formed of a silicon oxide film, for example. The floating gate 5 is formed on the gate insulating film 4 and has an acute-angled portion (tip portion) extending with an acute angle at an upper end thereof on a side of the control gate 9. At an erasure operation, the floating gate 5 emits electrons mainly from the acute-angled portion to the control gate 9. The floating gate 5 is made of polysilicon, for example. The spacer layer 6 is formed on the floating gate 5 except for an end of the acute-angled portion. The spacer layer 6 is formed of a silicon oxide film, for example. The first side wall insulating film 10 is formed so as to cover side surfaces of the gate insulating film 4, the floating gate 5 and the spacer layer 6 on a side of the source/drain electrode 7. The first side wall insulating film 10 is formed of a silicon oxide film, for example.

The tunnel insulating film 8 is formed so as to cover a region in the channel region C on a side of the source/drain region 12 (that is, a second surface region C2) and side surfaces of the gate insulating film 4, the floating gate 5 and the spacer layer 6. The tunnel insulating film 8 is formed of a silicon oxide film, for example. The control gate 9 is formed so as to cover the tunnel insulating film 8. A side surface of the control gate 9 is separated from the gate insulating film 4, the floating gate 5 and the spacer layer 6 through the tunnel insulating film 8. The control gate 9 is made of polysilicon, for example. The silicide layer 13 exemplified by a cobalt silicide film is formed on the control gate 9. The second side wall insulating film 11 is formed so as to cover the side surface of the control gate 9 on an opposite side to the floating gate 5. The second side wall insulating film 11 is formed of a silicon oxide film, for example.

According to the present invention, the tunnel insulating film 8 has following features. The tunnel insulating film 8 functions as the tunnel insulating film between the control gate 9 and the floating gate 5. On the other hand, the tunnel insulating film 8 functions as the gate insulating film between the control gate 9 and the semiconductor substrate 1 (well 2). In this connection, a thickness t2 of the tunnel insulating film 8 between the control gate 9 and the floating gate 5 is relatively small. On the other hand, a thickness t1 of the tunnel insulating film 8 between the control gate 9 and the semiconductor substrate 1 (well 2) is relatively large. For example, the thickness t2 of the tunnel insulating film 8 between the control gate 9 and the floating gate 5 is 15 nm and the thickness t1 of the tunnel insulating film 8 between the control gate 9 and the semiconductor substrate 1 (well 2) is about 16 nm. Therefore, the difference between the thickness t2 and the thickness t1 is 1 nm.

Next, referring to FIG. 3, operations (writing, reading and erasure) of the nonvolatile semiconductor memory according to the embodiment of the present invention will be described. Writing is performed by source side CHE (Channel Hot Electron) injection. At the writing operation, the source/drain region 3 functions as a drain (D) and the source/drain region 12 functions as a source (S). For example; a voltage of +1.6 V is applied to the control gate 9, a voltage of +7.6 V is applied to the source/drain region 3 and a voltage of +0.5 V is applied to the source/drain region 12. The electrons emitted from the source/drain region 12 are accelerated by an intense electric field in the channel region C and become CHEs. Especially, a potential of the floating gate 5 becomes higher due to capacitive coupling between the source/drain region 3 and the floating gate 5 and the intense electric field occurs in a narrow gap between the control gate 9 and the floating gate 5. The high energy CHEs generated by the intense electric field are injected into the floating gate 5 through the gate insulating film 4. Since electrons are injected into the floating gate 5, a threshold voltage of a memory cell increases.

At the reading operation, the source/drain region 3 functions as the source (S) and the source/drain region 12 functions as the drain (D). For example, a voltage of +2.5 V is applied to the control gate 9, a voltage of +0.8 V is applied to the source/drain region 12 and a voltage of 0 V is set to each of the source/drain region 3 and the well 2 on the semiconductor substrate 1. In an erased cell (for example, a memory cell in a state where no electrical charge is injected into the floating gate 5), the threshold voltage is low and a reading current (memory cell current) flows. On the other hand, in a written (program) cell (for example, a memory cell in a state where electrical charges are injected into the floating gate 5), the threshold voltage is high and the reading current (memory cell current) hardly flows. By detecting the reading current (memory cell current), it is possible to determine whether the cell is a program cell or the erased cell (that is, data “0” is stored or data “1” is stored).

The erasure operation is performed according to an F-N tunneling (Fowler-Nordheim Tunneling) method. For example, a voltage of +12.5 V is applied to the control gate 9 and a voltages of 0 V is set to each of the source/drain region 12, the source/drain region 3 and the well 2 on the semiconductor substrate 1. As a result, a high electric field is applied to the tunnel insulating film 8 between the control gate 9 and the floating gate 5 and an F-N current flows. Thereby, electrical charges (electrons) in the floating gate 5 are extracted to the control gate 9 through the tunnel insulating film 8.

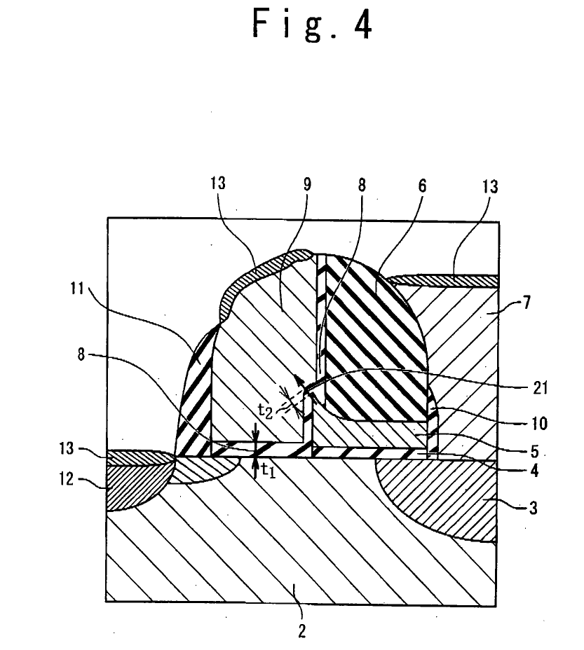

FIG. 4 is a sectional view showing one of features of the nonvolatile semiconductor memory according to the present embodiment. FIG. 4 is a partially enlarged view of FIG. 3. The tunnel insulating film 8 is continuously and integrally formed between the control gate 9 (side surface) and the floating gate 5, and between the control gate 9 (bottom surface) and the well 2 on the semiconductor substrate 1. However, a thickness t1 of the tunnel insulating film 8 between the control gate 9 and the well 2 (semiconductor substrate 1) is larger than a thickness t2 of the tunnel insulating film 8 between the control gate 9 and the floating gate 5. For this reason, at the data erasure operation, even when a high voltage is applied to the control gate 9, only an F-N current 21 flows from the floating gate 5 to the control gate 9 and no F-N current flows from the well 2 on the semiconductor substrate 1 to the control gate 9 (or even if the current flows, it is extremely small). As a result, the insulating film (tunnel insulating film 8) between the well 2 (semiconductor substrate 1) and the control gate 9 is hard to break down and the guaranteed number of times of rewriting can be prevented from decreasing.

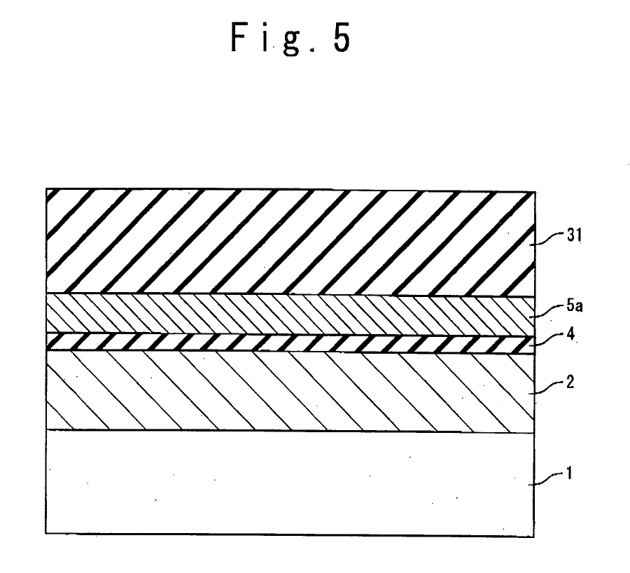

Next, the method of manufacturing the semiconductor device according to the embodiment of the present invention will be described. FIGS. 5 to 15 are sectional views showing the method of manufacturing the semiconductor device according to the present embodiment.

As shown in FIG. 5, first, the gate insulating film 4 (silicon oxide film) is formed so as to cover a surface of the p-type well 2 on the semiconductor substrate 1 made of silicon, for example, by using a thermal oxidation method. Next, a polysilicon film 5a for the floating gate is formed on the gate insulating film 4 by using a CVD (Chemical Vapor Deposition) method. After that, an interlayer insulating film (silicon nitride film) 31 is formed on the polysilicon film 5a by using the CVD method.

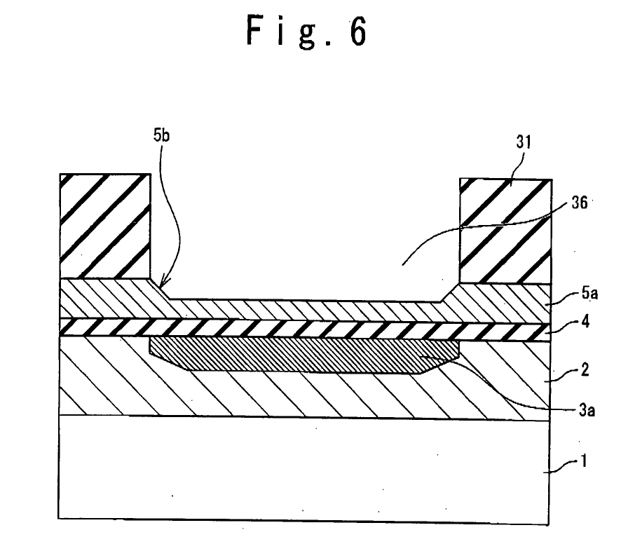

Next, as shown in FIG. 6, after a predetermined pattern of a photo resist (not shown) is formed, a groove pattern 36 is formed on the interlayer insulating film 31 by etching. Then, the photo resist is removed. Subsequently, using the interlayer insulating film 31 as a mask, an upper surface of the polysilicon film 5a is etched (slope etching) to form a slope 5b, which will constitute an upper surface of the acute-angled portion of the floating gate 5 later. Next, using the interlayer insulating film 31 as a mask, As or P ions are injected to form a low-density region 3a in the source/drain region 3 on the surface region of the well 2 on the semiconductor substrate 1.

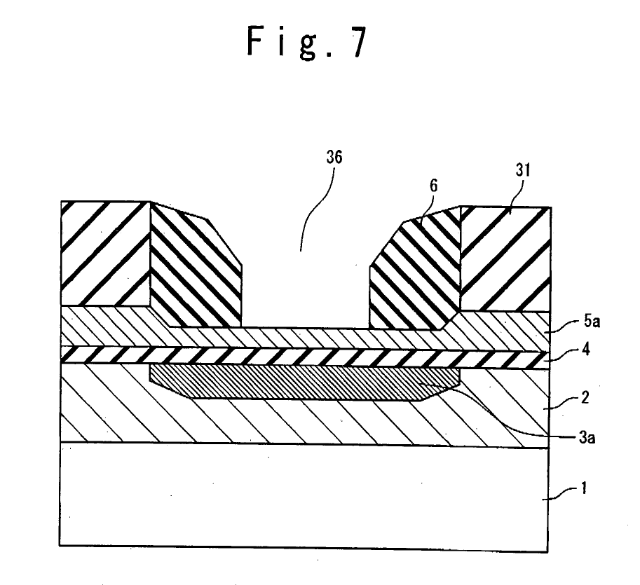

Subsequently, as shown in FIG. 7, a first insulating film (not shown) is formed so as to cover the interlayer insulating film 31 and the groove pattern 36 by using the CVD method. Then, the spacer layers 6 are formed on both inner side walls of the groove pattern 36 and on the polysilicon film 5a by etching back the first insulating film. The polysilicon film 5a is exposed between both the spacer layers 6.

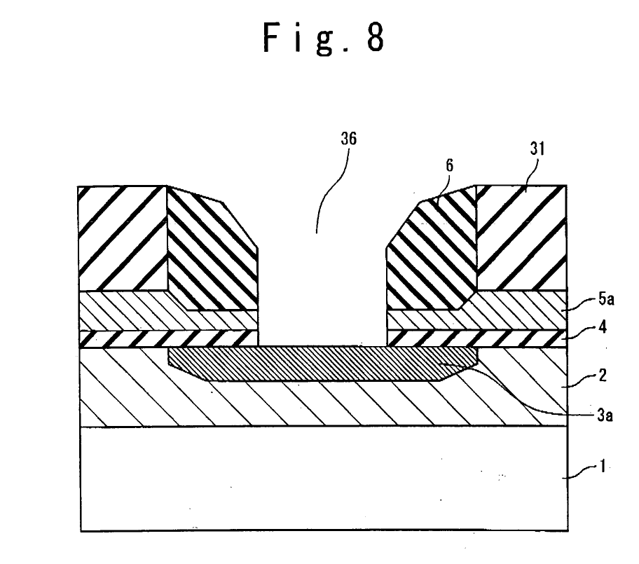

After that, as shown in FIG. 8, using the interlayer insulating film 31 and the spacer layer 6 as masks, the polysilicon film 5a and the gate insulating film 4 are etched. As a result, the low-density region 3a on the well 2 (semiconductor substrate 1) is exposed.

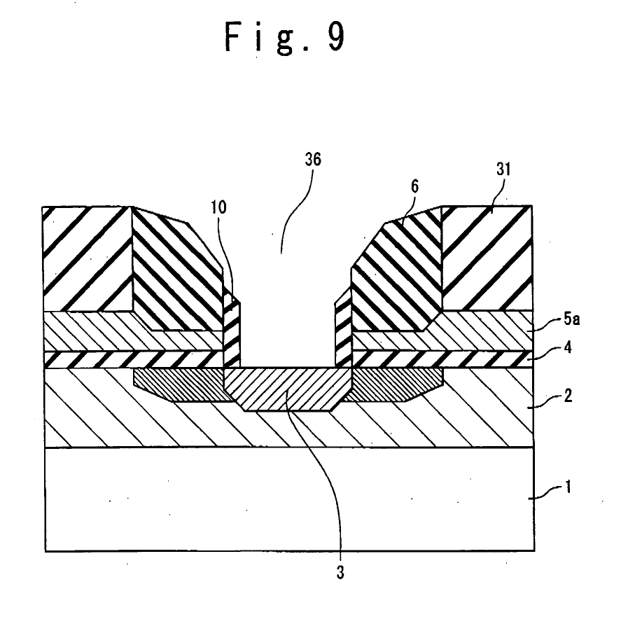

Next, as shown in FIG. 9, using the interlayer insulating film 31 and the spacer layer 6 as masks, As or P ions are injected to form the source/drain region 3. Then, a second insulating film (not shown) is formed so as to cover the interlayer insulating film 31, the spacer layer 6 and the groove pattern 36 by using the CVD method. Then, the second insulating film is etched back to form the first side wall insulating films 10 on inner side walls of the groove pattern 36 and on the first source/drain region 3. The source/drain region 3 is exposed between both of the first side wall insulating films 10.

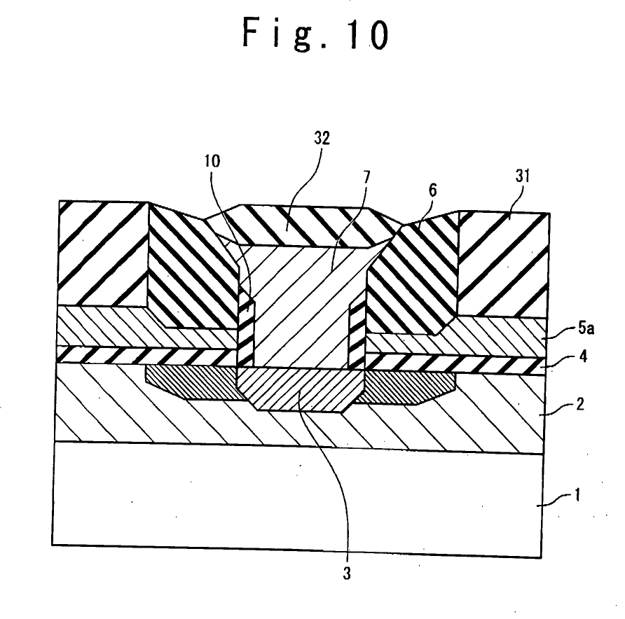

Subsequently, as shown in FIG. 10, a polysilicon film (not shown) for the source/drain electrode is formed so as to cover the interlayer insulating film 31, the spacer layer 6, the first side wall insulating film 10 and the groove pattern 36. Then, the polysilicon film is planarized by using a CMP (Chemical Mechanical Polishing) method and etched back, to form the source/drain electrode 7. Subsequently, As ions are injected into the source/drain electrode 7. Then, an upper portion of the source/drain electrode 7 is thermally oxidized to form a protective oxide film 32.

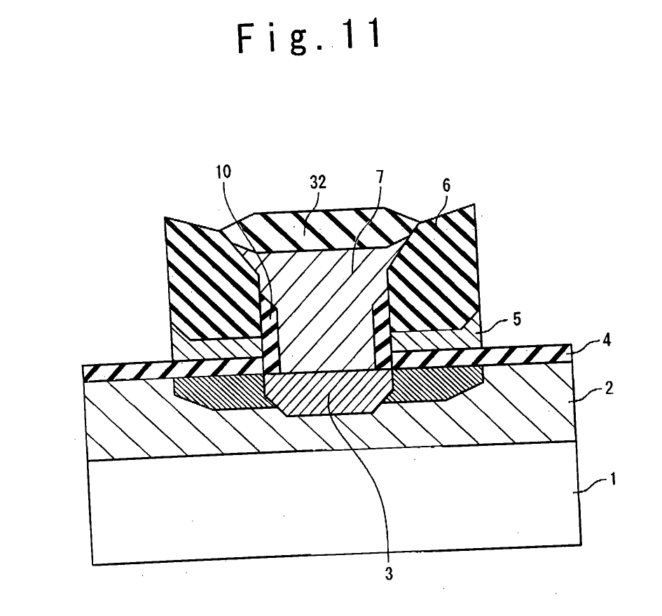

After that, as shown in FIG. 11, using the spacer layer 6 and the protective insulating film 32 as masks, the interlayer insulating film 31 is removed by etching. Then, using the spacer layers 6 and the protective insulating film 32 as masks, the polysilicon film 5a is etched to form the floating gate 5. The gate insulating film 4 except for portions under the spacer layer 6 and the floating gate 5 is exposed.

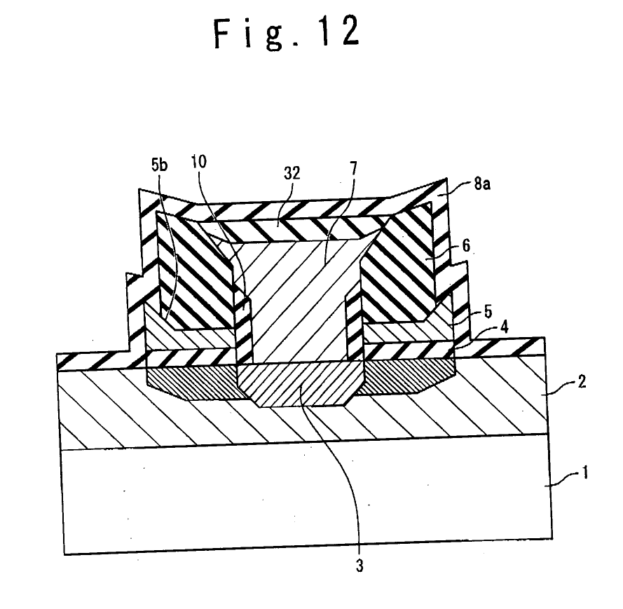

Next, as shown in FIG. 12, using the spacer layer 6 and the protective oxide film 32 as masks, the exposed gate insulating film 4 is removed by etching. Simultaneously, surfaces of the spacer layer 6 and the protective oxide film 32 are slightly etched. As a result, the acute-angled portion located at an end of the floating gate 5 having the slope 5b thereon is exposed. Subsequently, a tunnel insulating film 8a is formed by using the CVD method. It is desired that the tunnel insulating film 8a is an HTO (High Temperature Oxide) film. The reason is that an etching selective rate (wet etching) of a SOG oxide film 33 described later to the tunnel insulating film 8a can be high (ex. 10 or more).

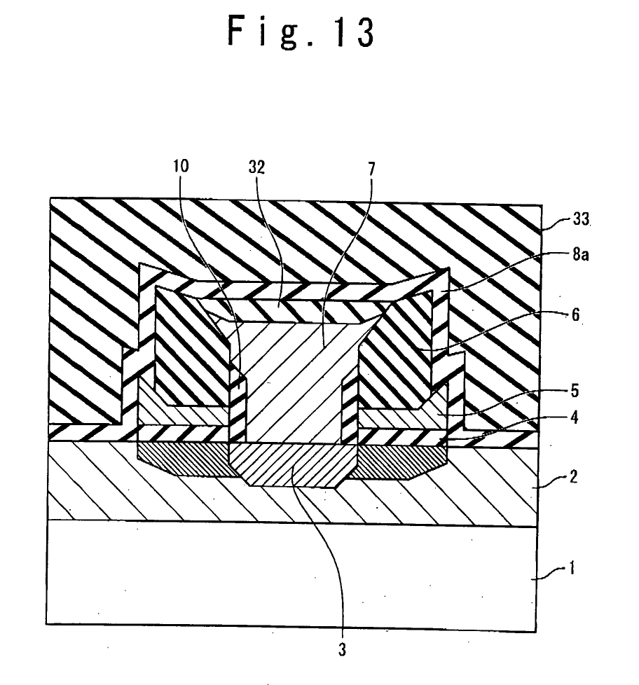

Subsequently, as shown in FIG. 13, the SOG oxide film 33 is formed so as to have such height to completely cover the tunnel insulating film 8a by rotational coating of SOG (Spin On Glass) material. Since the SOG oxide film is formed by rotational coating, at forming, sufficient flatness can be obtained. Since the upper surface of the SOG oxide film 33 is planarized, a thickness of the SOG oxide film 33 above the floating gate 5 and the spacer layer 6 (that is, above the region which becomes the channel region C1) and the source/drain electrode 7 is small, and the thickness of the SOG oxide film 33 above the other region (that is, above the region which becomes the channel region C2) is large. For example, based on the surface of the semiconductor substrate 1 (well 2), given that a highest position of the floating gate 5 is about 100 nm and a highest position of the spacer layer 6 is about 300 nm, a top surface of the SOG oxide film 33 is located at about 500 nm. In this case, the thickness of the SOG oxide film 33 above the floating gate 5, the spacer layer 6 and the source/drain electrode 7 is about 100 nm to 200 nm and the thickness of the SOG oxide film 33 above the other region in this figure is about 500 nm.

Since the SOG oxide film 33 is a sacrificial film which is removed in a later step as described later, its quality does not become an issue. Accordingly, thermal treatment which is normally performed after rotational coating (ex. 400 degrees centigrade) need not be performed. Although thermal treatment is performed to get rid of solvent, thereby densifying the film, a densified film is not necessarily needed in this step. Especially when below-mentioned etching-back is wet etching, it is preferred to omit thermal treatment as a large etching selective rate of the SOG oxide film to the tunnel insulating film 8a can be obtained.

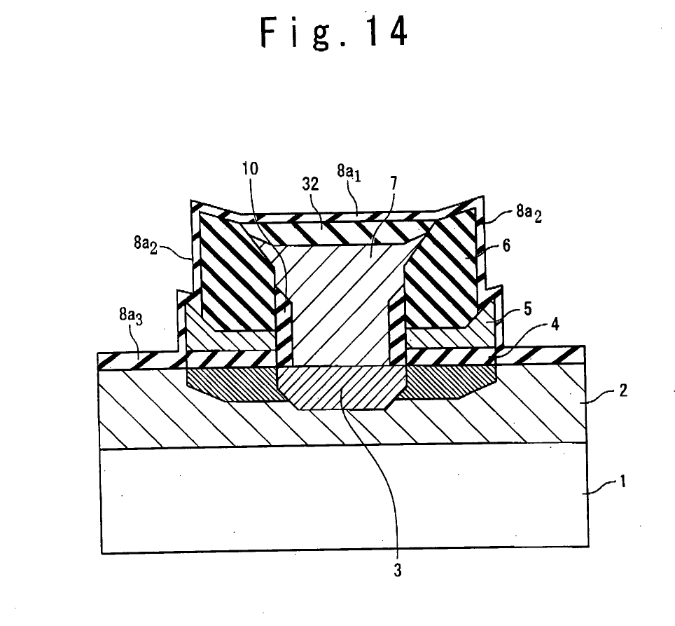

After that, as shown in FIG. 14, the SOG oxide film 33 is removed by etching-back. At this time, at a portion where the SOG oxide film 33 is rapidly removed, the tunnel insulating film 8a is exposed rapidly. For this reason, the exposed portion of the tunnel insulating film 8a is slightly etched and a thickness of the exposed portion is smaller than that of an unexposed portion. Here, the thickness of the SOG oxide film 33 above the floating gate 5, the spacer layer 6 and the source/drain electrode 7 is small. Thus, the portion above the floating gate 5, the spacer layer 6 and the source/drain electrode 7 is removed more rapidly than the other portion. As a result, in the tunnel insulating film 8a , a tunnel insulating film 8a1 above the floating gate 5, the spacer layer 6 and the source/drain electrode 7 is exposed first, a tunnel insulating film 8a2 on side surfaces of the spacer layer 6 is exposed next and a tunnel insulating film 8a3 in contact with the well 2 on the semiconductor substrate 1 is exposed last. When etching is performed until the SOG oxide film 33 is removed, the etching continues until the tunnel insulating film 8a3 is exposed. Thus, the tunnel insulating film 8a1 exposed first and the tunnel insulating film 8a2 exposed next are subjected to an etching atmosphere or an etching solution for a relatively long time. Although the method with a high etching selective rate of the SOG oxide film 33 to the tunnel insulating film 8a is adopted in etching, the tunnel insulating film 8a2 is etched a little. As a result, a thickness of the tunnel insulating film 8a1 through the tunnel insulating film 8a2 becomes smaller than that of the tunnel insulating film 8a3 due to etching. As a result, for example, the thickness of the tunnel insulating film 8a2 on an upper portion of the acute-angled portion on a side wall of the floating gate 5 can be made smaller than that of the tunnel insulating film 8a3 by about 1 nm, for example.

This etching-back may be wet etching, dry etching or combination of them. In terms of the etching selective rate of the SOG oxide film 33 to the tunnel insulating film 8a, wet etching is preferable. For example, when the SOG oxide film 33 is not thermally treated and the tunnel insulating film 8a is an HTO film formed by using the CVD method, the selective rate in wet etching (by using buffered HF with a predetermined concentration) is 10 or more (etching rate of the SOG film is 10 times or more as large as the HTO film). Consequently, since the SOG oxide film 33 is sequentially etched from the top, when etching time is appropriately controlled, the tunnel insulating film 8a on the side wall of the floating gate 5 is slightly etched from its top and becomes thinner, the tunnel insulating film 8a between a region on a bottom where the control gate 9 is formed and the semiconductor substrate 1 (well 2) can be sufficiently left and the SOG oxide film 33 can be completely removed. Even when the spacer layer 6 on the floating gate 5 and the tunnel insulating film 8a on a side wall of the spacer layer 6 are etched, it is of no matter. As described above, the combination of film types and the etching method, which can obtain a high selective rate of the SOG oxide film 33 to the tunnel insulating film 8a, are preferable.

In a case of dry etching, since anisotropic etching is performed, the SOG oxide film 33 may be left at a lower portion Of the side wall of the floating gate 5. However, even if the SOG oxide film 33 is left there, it causes no problem.

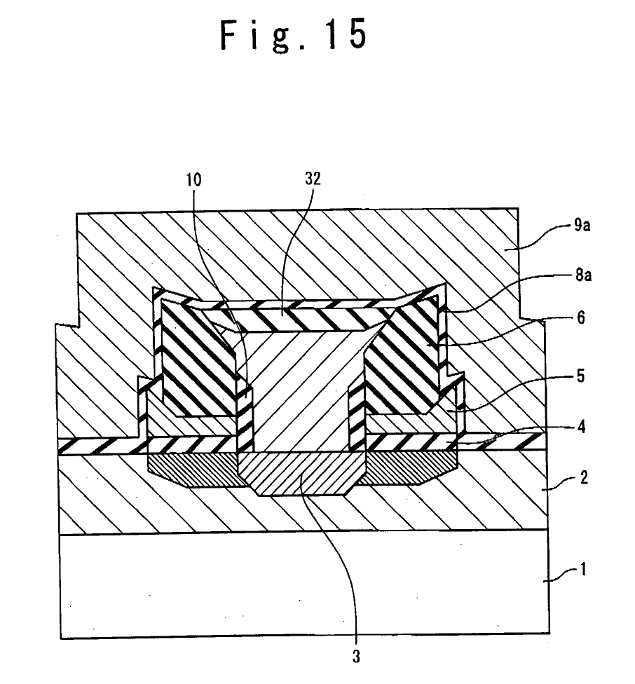

Next, as shown in FIG. 15, a polysilicon film 9a for the control gate is formed so as to cover the tunnel insulating film 8a by using the CVD method. After that, as shown in FIG. 3, the polysilicon film 9a is etched back to form the side wall-like control gate 9 lateral to the spacer layer 6 and the floating gate 5 through the tunnel insulating film 8a. Next, using the control gate 9 and the tunnel insulating film 8a as masks, As or P ions are injected to form a low-density region 12a in the source/drain region 12 on the surface region of the well 2 on the semiconductor substrate 1. Subsequently, a third insulating film (not shown) is formed so as to cover the surface by using the CVD method. Then, the third insulating film is etched back to form the second side wall insulating film 11 lateral to the control gate 9. After that, using the control gate 9, the tunnel insulating film 8a and the second side wall insulating film 11 as masks, As or P ions are injected to form the source/drain region 12 on an outer side of the second side wall insulating film 11 and on the surface region of the well 2 on the semiconductor substrate 1. Next, top portions of the source/drain region 12, the control gate 9 and the source/drain electrode 7 are exposed by etching. At this time, the tunnel insulating film 8a becomes the tunnel insulating film 8. Subsequently, a cobalt film is formed by using a sputtering method, and subjected to thermal treatment such that the top portions of the source/drain region 12, the control gate 9 and the source/drain electrode 7 are silicided to form the silicide film 13. Then, the unsilicided cobalt film is removed by etching.

The semiconductor device (nonvolatile semiconductor memory) according to the present embodiment can be manufactured in this manner.

According to the method of manufacturing the semiconductor device of the present invention, the SOG oxide film 33 is formed so as to cover the tunnel insulating film 8a, be thick above the channel region C2 (the region where the control gate 9 is formed) and be thin above the floating gate 5. For this reason, when the SOG oxide film 33 is etched back, the SOG oxide film 33 above and lateral to the floating gate 5 is removed sooner, while the SOG oxide film 33 above the channel region C2 is removed later. Thus, when etching-back is continued until the SOG oxide film 33 above the channel region C2 is completely removed, the SOG oxide film 33 above and lateral to the floating gate 5 is removed sooner and subsequently, surfaces of the tunnel insulating films 8a1, 8a2 are also etched back. As a result, the tunnel insulating film 8a3 above the channel region C2 is hardly etched back and the tunnel insulating films 8a1, 8a2 above and lateral to the floating gate 5 are etched back by a relatively large amount. In other words, the tunnel insulating film 8a3 above the channel region C2 becomes relatively thick and the tunnel insulating films 8a1, 8a2 above and lateral to the floating gate 5 become relatively thin. In this manner, the thickness t1 of the tunnel insulating film 8 between the control gate 9 and the well 2 (semiconductor substrate 1) is larger than the thickness t2 of the tunnel insulating film 8 between the control gate 9 and the floating gate 5. For this reason, at the data erasure operation, even when a high voltage is applied to the control gate 9, in passing the F-N current 21 from the floating gate 5 to the control gate 9, the F-N current can be prevented from flowing from the well 2 on the semiconductor substrate 1 to the control gate 9 (or even if the F-N current flows, the amount is extremely small). As a result, the insulating film (tunnel insulating film 8) between the well 2 (semiconductor substrate 1) and the control gate 9 is hard to break down, thereby enabling prevention of a decrease in the guaranteed number of times of rewriting.

In addition, according to the above-mentioned manufacturing method, at the step of making the thickness t1 of the tunnel insulating film 8 larger than the thickness t2 of the tunnel insulating film 8, the step of covering the interface of the tunnel insulating film 8a with the SOG oxide film 33 and then, etching back the SOG oxide film 33 is used and the resist film is not used. For this reason, the interface of each insulating film is not contaminated. Therefore, according to the present invention, contamination of the interface of the insulating film such as the tunnel insulating film 8a can be prevented. Thereby, reliability of the nonvolatile semiconductor memory can be prevented from lowering.

As described above, according to the present invention, by preventing contamination of the interface of the insulating film, the reliability of the nonvolatile semiconductor memory can be prevented from lowering; Furthermore, by making the thickness of the tunnel insulating film between the control gate and the semiconductor substrate larger than that of the tunnel insulating film between the control gate and the floating gate, breakdown of the insulating film between the semiconductor substrate and the control gate can be suppressed, thereby preventing a decrease in the guaranteed number of times of rewriting.

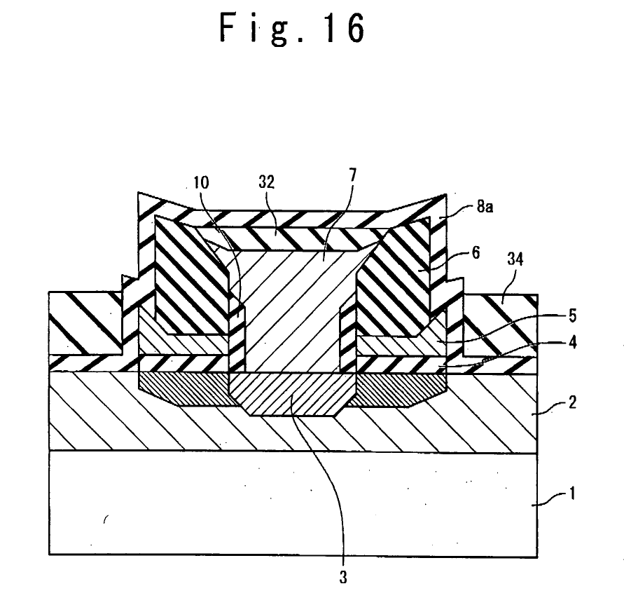

Next, a variation of the method of manufacturing the semiconductor device according to the present embodiment will be described. In FIG. 13, the SOG oxide film 33 is formed so as to cover a whole of the tunnel insulating film 8a. However, the SOG oxide film 33 may be formed so that the tunnel insulating film 8a is partially exposed. FIG. 16 is a sectional view showing another variation of the method of manufacturing the semiconductor device according to the present embodiment. A height of an SOG oxide film 34 is smaller than that of the spacer layer 6 and is the substantially the same as that of the floating gate 5, for example. In order to form such SOG oxide film 34, an amount of an SOG material may be appropriately decreased and the number of rotations may be appropriately increased at rotational coating. However, a very thin SOG oxide film is formed on the spacer layer 6 and the tunnel insulating film 8a of the protective oxide film 32. However, since the SOG oxide film is removed at a very initial stage in etching-back of the SOG oxide film 34, it can be said that the SOG oxide film does not practically exist.

When the step shown in FIG. 16 is adopted, a similar effect to that obtained by the step in FIG. 13 can be obtained.

It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A method of manufacturing a semiconductor device comprising:
forming a floating gate on a first surface region of a semiconductor substrate through a gate insulating film;
forming a tunnel insulating film so as to cover a second surface region adjacent to said first surface region and an end portion of said floating gate;
forming an oxide film so as to cover said tunnel insulating film and be thicker at a portion above said second surface region than at a portion above said floating gate;
etching back said oxide film and a surface of said tunnel insulating film on said floating gate; and
forming a control gate on said tunnel insulating film on said second surface region.

2. The method of manufacturing a semiconductor device according to claim 1, wherein said step of forming said oxide film, includes:
forming said oxide film so as to cover said tunnel insulating film on said second surface region and so as not to cover said tunnel insulating film above said floating gate.

3. The method of manufacturing a semiconductor device according to claim 1, wherein said step of forming said oxide film, includes:
forming a SOG (Spin On Glass) oxide film as said oxide film by rotational coating of SOG material.

4. The method of manufacturing a semiconductor device according to claim 2, wherein said step of forming said oxide film, includes:
forming a SOG (Spin On Glass) oxide film as said oxide film by rotational coating of SOG material.

5. The method of manufacturing a semiconductor device according to claim 3, wherein said step of forming said oxide film, further includes:
performing thermal treatment on said SOG oxide film.

6. The method of manufacturing a semiconductor device according to claim 4, wherein said step of forming said oxide film, further includes:
performing thermal treatment on said SOG oxide film.

7. The method of manufacturing a semiconductor device according to claim 1, wherein one of wet etching, dry etching and a combination of wet etching and dry etching is used in said step of etching back said oxide film.

8. The method of manufacturing a semiconductor device according to claim 2, wherein one of wet etching, dry etching and a combination of wet etching and dry etching is used in said step of etching back said oxide film.

9. The method of manufacturing a semiconductor device according to claim 3, wherein one of wet etching, dry etching and a combination of wet etching and dry etching is used in said step of etching back said oxide film.

10. The method of manufacturing a semiconductor device according to claim 4, wherein one of wet etching, dry etching and a combination of wet etching and dry etching is used in said step of etching back said oxide film.

11. The method of manufacturing a semiconductor device according to claim 5, wherein one of wet etching, dry etching and a combination of wet etching and dry etching is used in said step of etching back said oxide film.

12. The method of manufacturing a semiconductor device according to claim 6, wherein one of wet etching, dry etching and a combination of wet etching and dry etching is used in said step of etching back said oxide film.

13. The method of manufacturing a semiconductor device according to claim 1, wherein said step of forming said tunnel insulating film, includes:
forming a HTO (High Temperature Oxide) film as said tunnel insulating film,
wherein said step of forming said oxide film, includes:
forming a SOG (Spin On Glass) oxide film as said oxide film by rotational coating of SOG material,
wherein said step of etching back said oxide film, includes:
etching back said oxide film and a part of said tunnel insulating film by wet etching.

14. The method of manufacturing a semiconductor device according to claim 1, wherein said step of etching back said oxide film, includes:
etching back said oxide film and said surface of said tunnel insulating film such that said oxide film is removed and said tunnel insulating film is thicker at a portion above said second surface region than at said end portion of said floating gate.

15. The method of manufacturing a semiconductor device according to claim 1, wherein said semiconductor device includes a nonvolatile semiconductor memory.
